(19) United States
(12) Patent Application Publication
(10) Pub. No.: US 2012/0250270 A1
(43) Pub. Date: Oct. 4, 2012

(54) PROTECTIVE CASING ADAPTED FOR ELECTRONIC DEVICE

(76) Inventor: Wen-Chin Liu, New Taipei City (TW)

(21) Appl. No.: 13/074,012

(22) Filed: Mar. 29, 2011

(51) Int. Cl. H05K 5/03; B65D 85/00

(52) U.S. Cl. 361/752; 206/776

(57) ABSTRACT

A protective casing adapted for an electronic device includes a lower casing, an upper casing and a back cover. The upper casing cooperates with the lower casing to form a first accommodating space therebetween. The back cover is detachably accommodated in the first accommodating space and used to house the electronic device.

### BACKGROUND OF THE INVENTION

1. Field of the Invention

The invention relates to a protective casing and, more particularly, to a protective casing equipped with a back cover for housing an electronic device.

2. Description of the Prior Art

As technology advances, various electronic devices including mobile phone, media player (e.g. MP3 player), personal digital assistant (PDA) and so on have been developed to make life more convenient and colorful. In order to protect the electronic device from harm, a user may use a protective casing to accommodate the electronic device. In the prior art, there are various protective casings adapted for various electronic devices respectively; that is, each kind of protective casing can only be used to accommodate one specific electronic device. Therefore, if the user has more than one electronic device, he or she has to buy more than one protective casing for each electronic device correspondingly. As a result, it is inevitable to increase additional cost.

### SUMMARY OF THE INVENTION

An objective of the invention is to provide a protective casing equipped with a back cover for housing an electronic device, so as to solve the aforesaid problem.

According to one embodiment of the invention, a protective casing adapted for an electronic device comprises a lower casing, an upper casing and a back cover. The upper casing cooperates with the lower casing to form a first accommodating space therebetween. The back cover is detachably accommodated in the first accommodating space and used to house the electronic device. In other words, the electronic device can be accommodated in the first accommodating space together with the back cover. On the other hand, another electronic device can be also accommodated in the first accommodating space without the back cover.

As mentioned in the above, since the protective casing of the invention can be used to accommodate different electronic devices with or without the back cover, the protective casing of the invention equipped with the back cover will save cost for the user.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a protective casing in a closed state according to one embodiment of the invention.

FIG. 2 is a perspective view illustrating the protective casing in FIG. 1 from another view angle.

FIG. 3 is a perspective view illustrating the protective casing in FIG. 1 in an opened state.

FIG. 4 is a perspective view illustrating the protective casing in FIG. 4 with detached back cover.

FIG. 5(A) and FIG. 5(B) are perspective views illustrating the back cover in FIG. 4 used to house an electronic device from different view angles.

FIG. 6(A) and FIG. 6(B) are exploded views illustrating the back cover and the electronic device in FIG. 5(A) and FIG. 5(B) from different view angles.

FIG. 7 is a perspective view illustrating the back cover in FIG. 6 from another view angle.

FIG. 8 is a perspective view illustrating the electronic device housed on the back cover and accommodated in the first accommodating space together with the back cover in FIG. 4.

FIG. 9 is an exploded view illustrating the lower casing in FIG. 4.

FIG. 10 illustrates another electronic device and the electronic device housed on the back cover, wherein FIG. 10(A) is a perspective view, FIG. 10(B) is a front view, and FIG. 10(C) is a side view.

FIG. 11 is a perspective view illustrating the electronic device accommodated in the first accommodating space without the back cover.

FIG. 12 is a perspective view illustrating the electronic device in FIG. 10 disposed on the partition member in FIG. 9.

### DETAILED DESCRIPTION

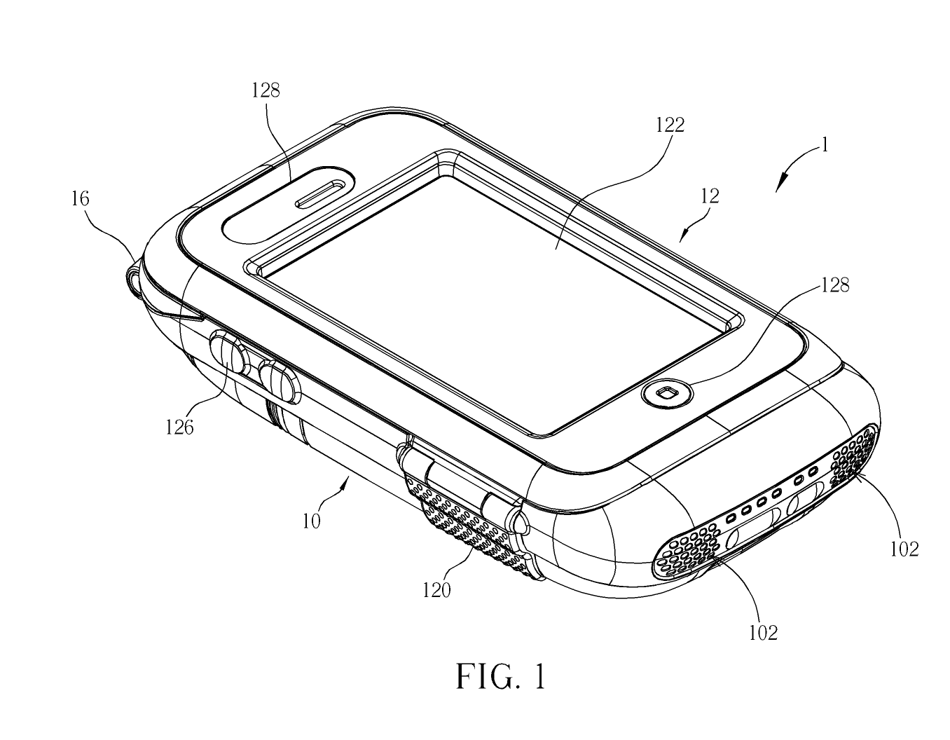

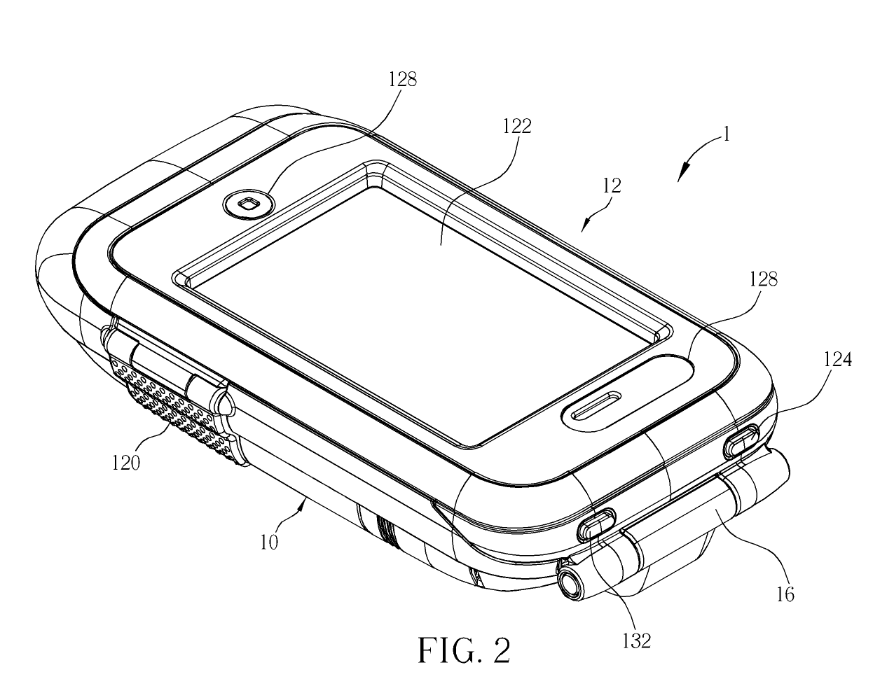

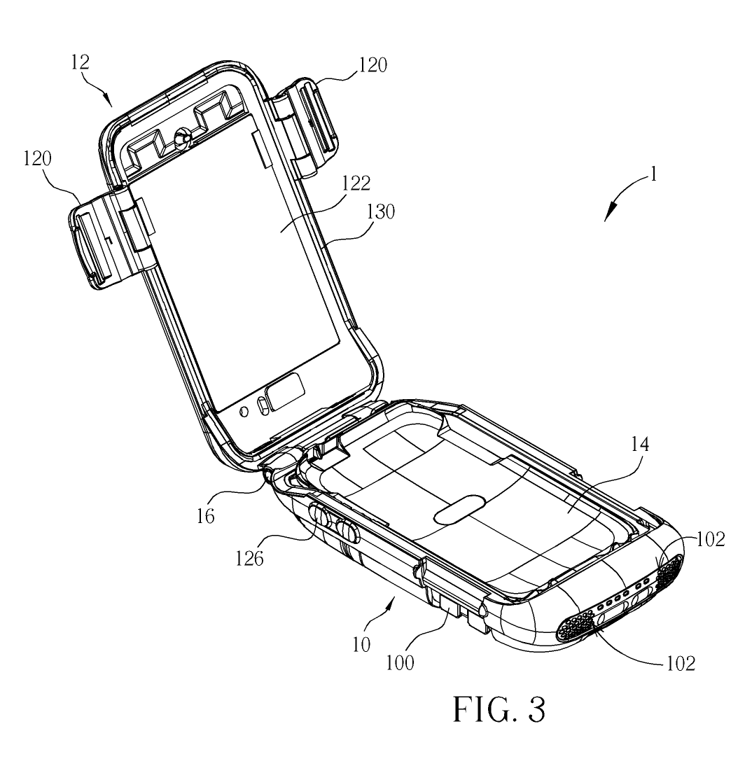

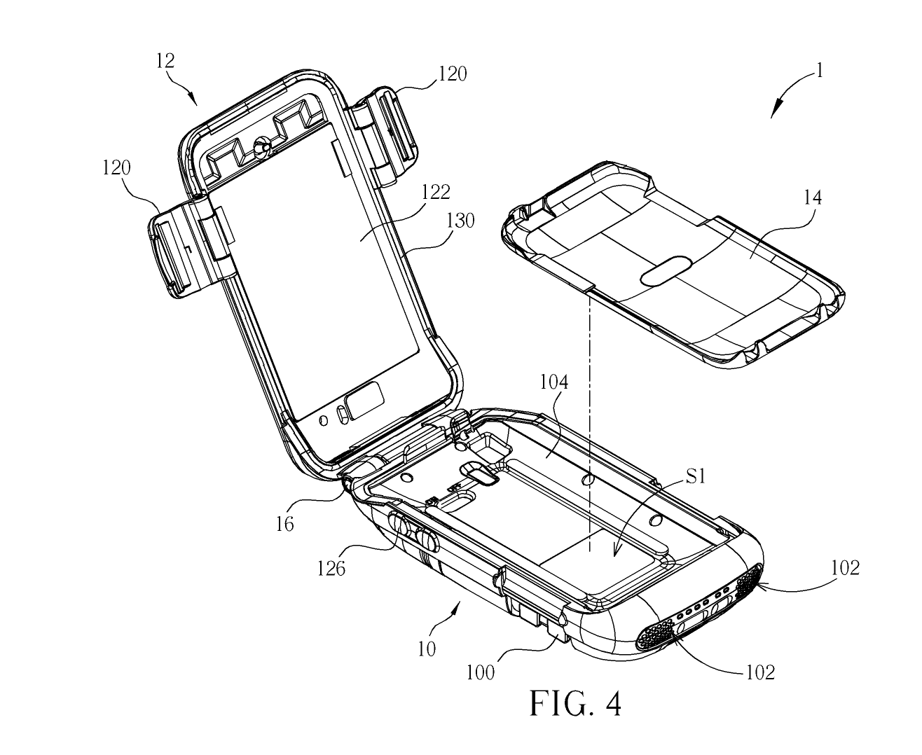

Referring to FIGS. 1 to 4, FIG. 1 is a perspective view illustrating a protective casing 1 in a closed state according to one embodiment of the invention, FIG. 2 is a perspective view illustrating the protective casing 1 in FIG. 1 from another view angle, FIG. 3 is a perspective view illustrating the protective casing 1 in FIG. 1 in an opened state, and FIG. 4 is a perspective view illustrating the protective casing 1 in FIG. 4 with detached back cover 14.

As shown in FIGS. 1 to 4, the protective casing 1 comprises a lower casing 10, an upper casing 12 and a back cover 14. The upper casing 12 cooperates with the lower casing 10 to form a first accommodating space S1 therebetween. The back cover 14 can be detachably accommodated in the first accommodating space S1, as shown in FIGS. 3 and 4. In this embodiment, the protective casing 1 may further comprise a hinge assembly 16 for pivotally connecting the upper casing 12 to the lower casing 10. Furthermore, the upper casing 12 may comprise two fastener members 120 pivotally connected to opposite sides of the upper casing 12, the lower casing 10 may comprise two fastener structures 100 formed on opposite sides of the lower casing 10, and the two fastener members 120 can be detachably fastened on the two fastener structures 100 respectively.

It should be noted that there is only one fastener structure 100 shown in FIG. 3 due to the view angle. As the closed state shown in FIGS. 1 and 2, the two fastener members 120 are fastened on the two fastener structures 100 respectively to fix the upper casing 12 and the lower casing 10. On the other hand, after the two fastener members 120 are detached from the two fastener structures 100 respectively and the upper casing 12 rotates with respect to the lower casing 10 via the hinge assembly 16, the protective casing 1 is in the opened state as shown in FIGS. 3 and 4. Accordingly, a user can operate the protective casing 1 between the closed state and the opened state.

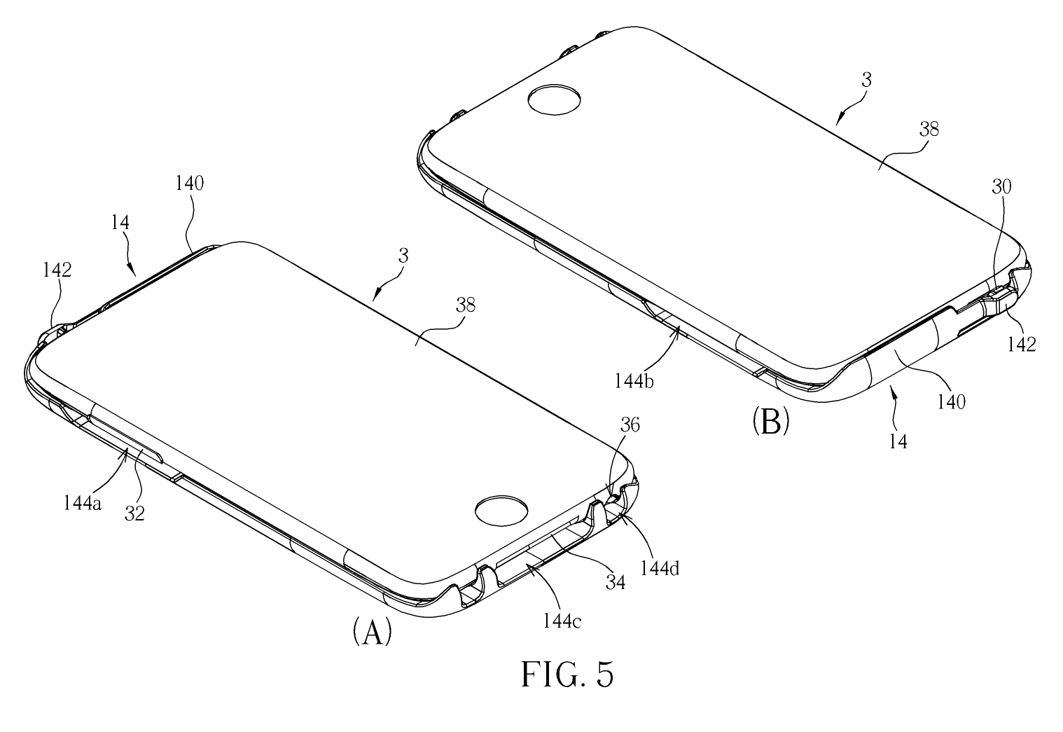

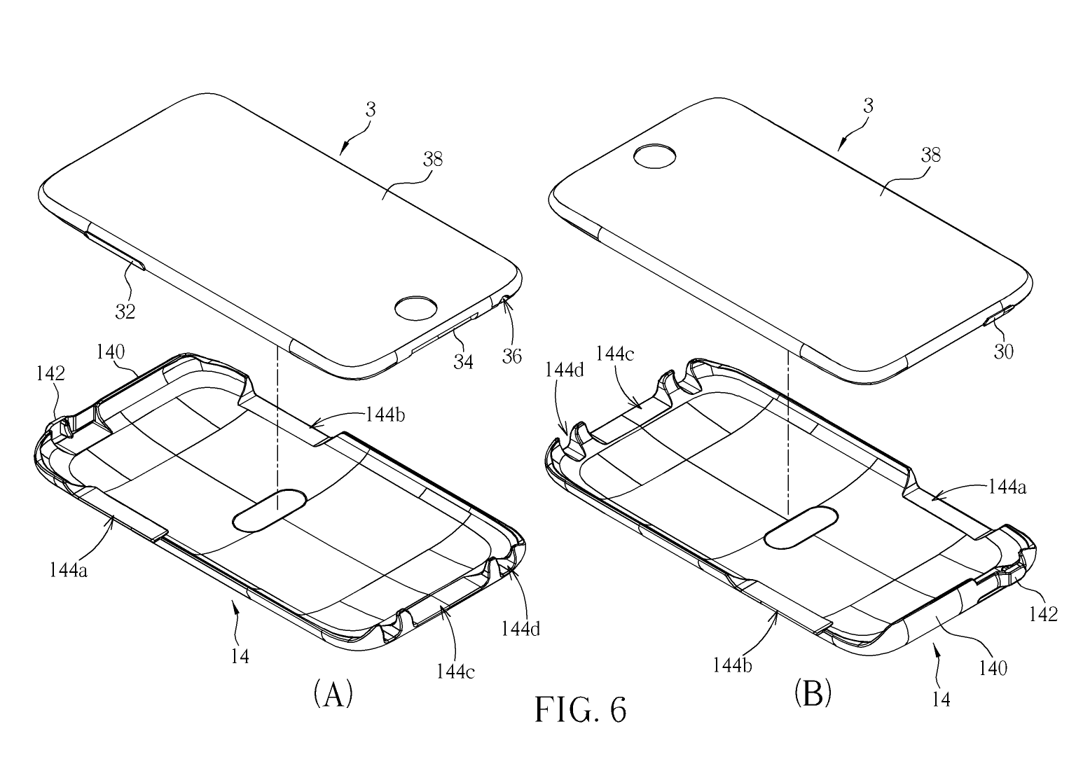

Referring to FIGS. 5 and 6, FIG. 5(A) and FIG. 5(B) are perspective views illustrating the back cover 14 in FIG. 4 used to house an electronic device 3 from different view angles, and FIG. 6(A) and FIG. 6(B) are exploded views illustrating the back cover 14 and the electronic device 3 in FIG. 5(A) and FIG. 5(B) from different view angles.

The electronic device 3 may be a mobile phone, media player (e.g. MP3 player), personal digital assistant (PDA) and so on. In this embodiment, the back cover 14 has an engaging structure 140 extending from a periphery of the back cover 14, and the engaging structure 140 is used to engage the electronic device 3, such that the user can use the back cover 14 to house the electronic device 3. The engaging structure 140 may be, but not limited to, arc-shaped claws. As shown in FIG. 6, the electronic device 3 may have a power button 30, and the back cover 14 may have a resilient arm 142 extending from the periphery of the back cover 14 and corresponding to the power button 30 of the electronic device 3. As shown in FIG. 5, when the electronic device 3 is housed on the back cover 14 and engaged with the engaging structure 140, the resilient arm 142 abuts against the power button 30. Therefore, the user can press the resilient arm 142 to trigger the power button 30, so as to power on/off the electronic device 3.

In this embodiment, there may be at least one recess formed on the periphery of the back cover 14 and corresponding to at least one connector and/or button disposed on a periphery of the electronic device 3. As shown in FIG. 6, the electronic device 3 may have a button 32 (e.g. volume adjusting button) disposed on one side of the electronic device 3, so a first recess 144a maybe formed on one side of the back cover 14 and corresponding to the button 32. As shown in FIG. 5, when the electronic device 3 is housed on the back cover 14 and engaged with the engaging structure 140, the button 32 is exposed from the first recess 144a. Accordingly, the user can operate the button 32 via the first recess 144a. Furthermore, a second recess 144b may be formed on another side of the back cover 14 and opposite to the first recess 144a. Accordingly, the user can grab opposite sides of the electronic device 3 via the first and second recesses 144a, 144b and then detaches the electronic device 3 from the back cover 14 easily.

Moreover, as shown in FIG. 6, there also maybe other recesses 144c, 144d formed on another side of the back cover 14 and corresponding to connectors 34, 36 (e.g. USB connector, audio jack connector, etc.) disposed on the periphery of the electronic device 3. As shown in FIG. 5, when the electronic device 3 is housed on the back cover 14 and engaged with the engaging structure 140, the connectors 34, 36 are exposed from the recesses 144c, 144d respectively. Accordingly, the user can operate the connectors 34, 36 via the recesses 144c, 144d.

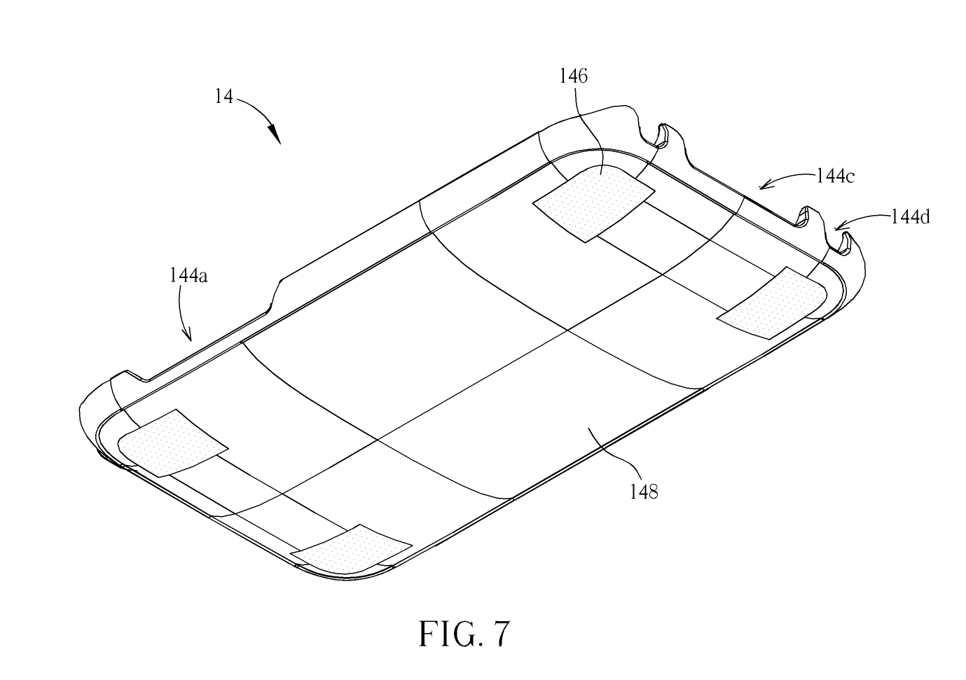

Referring to FIG. 7, FIG. 7 is a perspective view illustrating the back cover 14 in FIG. 6 from another view angle. As shown in FIG. 7, a skidproof structure 146 may be formed on an outer surface 148 of the back cover 14 by surface treatment, such as texture process, printing process, laser marking process and so on. In addition, the skidproof structure 146 may be formed as various patterns for purpose of decoration.

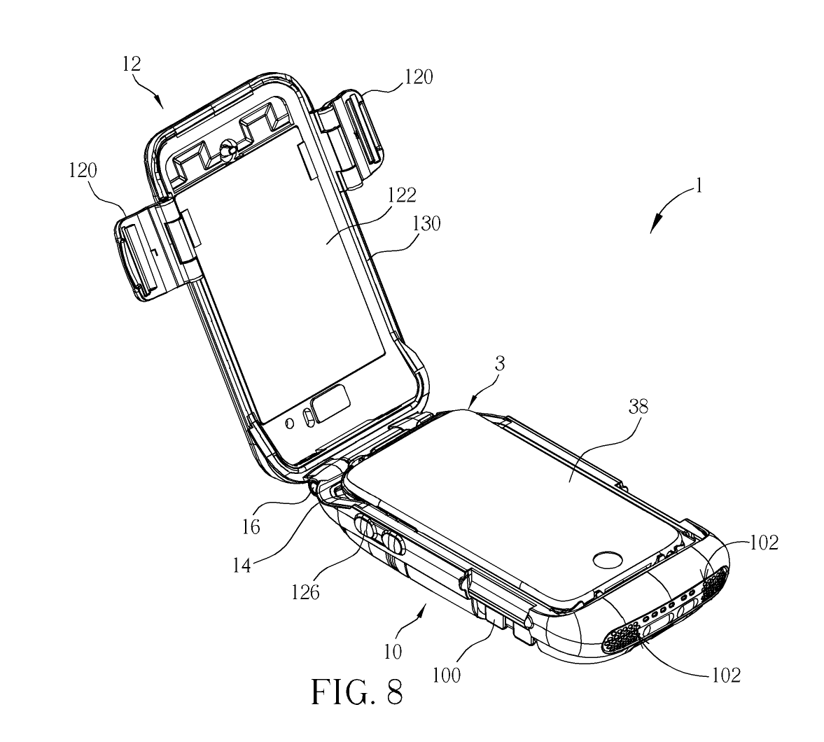

Referring to FIG. 8, FIG. 8 is a perspective view illustrating the electronic device 3 housed on the back cover 14 and accommodated in the first accommodating space S1 together with the back cover 14 in FIG. 4. As shown in FIGS. 4, 5 and 8, after housing the electronic device 3 on the back cover 14, the electronic device 3 can be accommodated in the first accommodating space S1 together with the back cover 14. In this embodiment, the upper casing 12 may comprise a transparent sheet 122 (e.g. PET film). When the electronic device 3 is accommodated in the first accommodating space S1 together with the back cover 14 and when the protective casing 1 is in the closed state (as shown in FIG. 1), a touch panel 38 of the electronic device 3 abuts against the transparent sheet 122. Accordingly, the user may perform tactile operation to the touch panel 38 via the transparent sheet 122.

Furthermore, the upper casing 12 may have a key structure 124 (as shown in FIG. 2) corresponding to the resilient arm 142 of the back cover 14 (as shown in FIG. 5). In this manner, when the electronic device 3 is accommodated in the protective casing 1 together with the back cover 14, the user can press the key structure 124 to drive the resilient arm 142 to trigger the power button 30, so as to power on/off the electronic device 3. Still further, the lower casing 10 may have a key structure 126 (as shown in FIG. 1) corresponding to the first recess 144a of the back cover 14 and the button 32 of the electronic device 3 (as shown in FIG. 5). In this manner, when the electronic device 3 is accommodated in the protective casing 1 together with the back cover 14, the user can press the key structure 126 to trigger the button 32 via the first recess 144a, so as to operate the button 32.

As shown in FIG. 1, there is at least one hole 128 formed on the upper casing 12 for specific purposes (e.g. light emitting hole, button hole, etc.), and the upper casing 12 may comprise at least one waterproof member (e.g. waterproof film or waterproof glue, not shown) covering the at least one hole 128 respectively, so as to prevent water from entering the protective casing 1 via the at least one hole 128. Furthermore, there is at least one hole 102 formed on the lower casing 10 for specific purposes (e.g. speaker hole, microphone hole, etc.), and the lower casing 10 may also comprise at least one waterproof member (e.g. waterproof film or waterproof glue, not shown) covering the at least one hole 102 respectively, so as to prevent water from entering the protective casing 1 via the at least one hole 102. Moreover, the upper casing 12 may comprise a ring-shaped waterproof member 130 disposed on an inner side of the upper casing 12, as shown in FIG. 3. When the protective casing 1 is in the closed state shown in FIG. 1, the ring-shaped waterproof member 130 can prevent water from entering the protective casing 1 via the junction between the upper casing 12 and the lower casing 10.

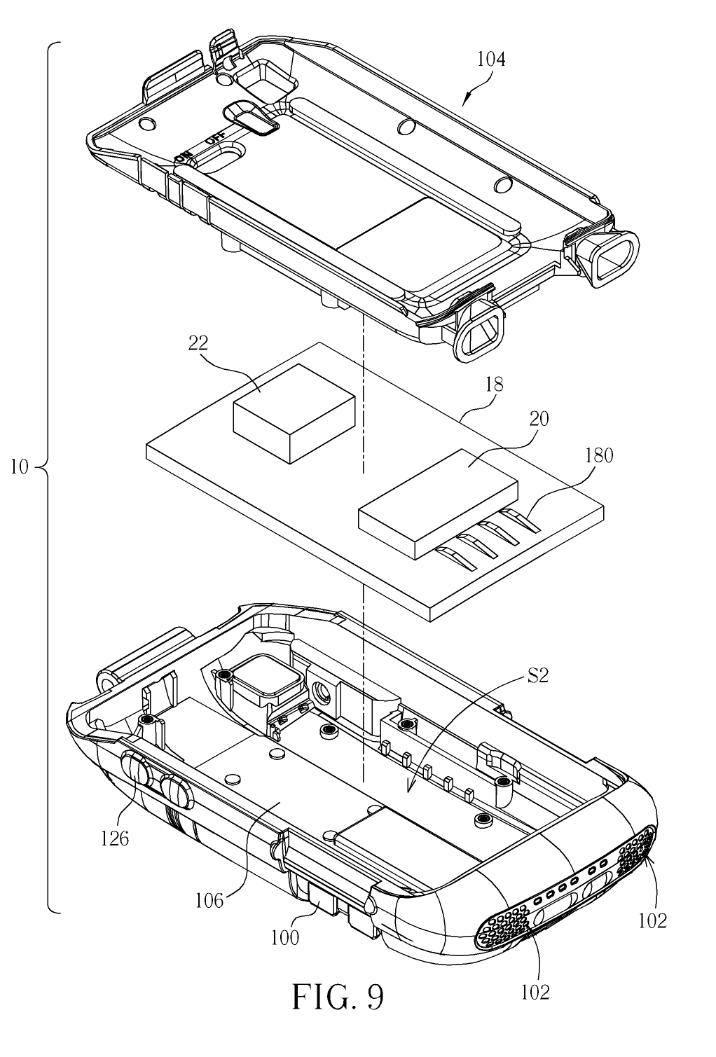

Referring to FIG. 9, FIG. 9 is an exploded view illustrating the lower casing 10 in FIG. 4. As shown in FIGS. 4 and 9, the lower casing 10 comprises a partition member 104 disposed therein. The first accommodating space S1 is above the partition member 104, and a second accommodating space S2 is between the partition member 104 and a bottom 106 of the lower casing 10. In this embodiment, the protective casing 1 may further comprise a circuit board 18 and a power supply unit 20 disposed in the second accommodating space S2. The power supply unit 20 is electrically connected to the circuit board 18. When the aforesaid electronic device 3 is housed on the back cover 14 and accommodated in the first accommodating space S1 together with the back cover 14, a connector (not shown) of the electronic device 3 is electrically connected to a connector 180 of the circuit board 18, such that the power supply unit 20 can supply power to the electronic device 3. In this manner, the operating time of the electronic device 3 can be effectively extended. In practical applications, the power supply unit 20 may be, but not limited to, a battery.

As shown in FIG. 9, the protective casing 1 may further comprise a positioning unit 22 disposed in the second accommodating space S2 and electrically connected to the circuit board 18. In practical applications, the positioning unit 22 may be, but not limited to, a Global Positioning System (GPS). The positioning unit 22 can be used to assist the electronic device 3 in positioning itself once the electronic device 3 cannot position itself precisely.

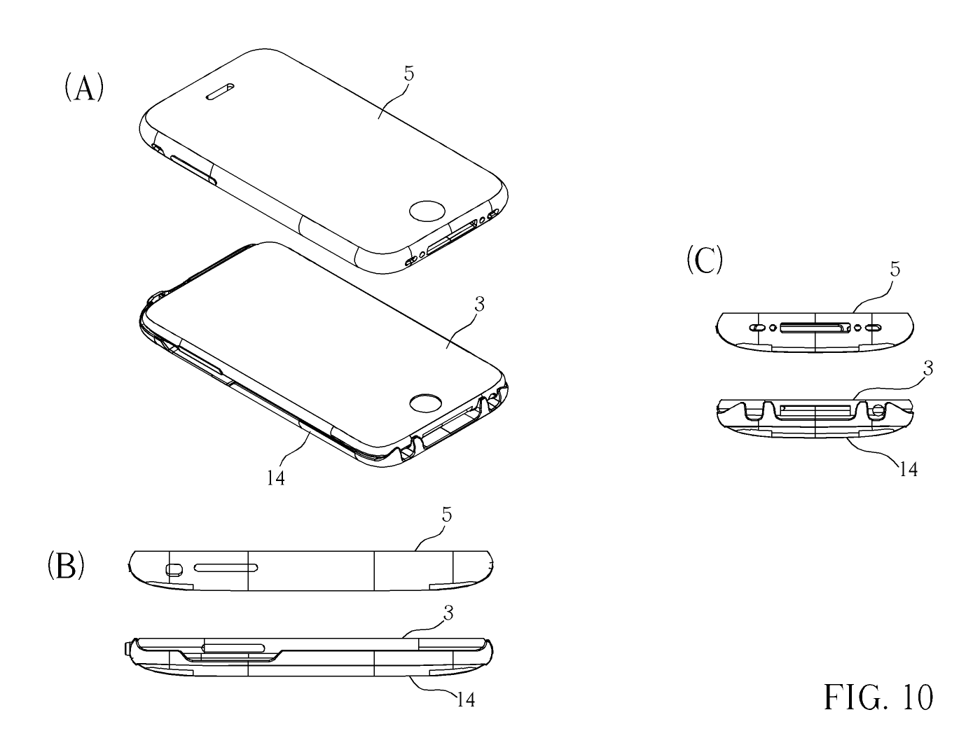

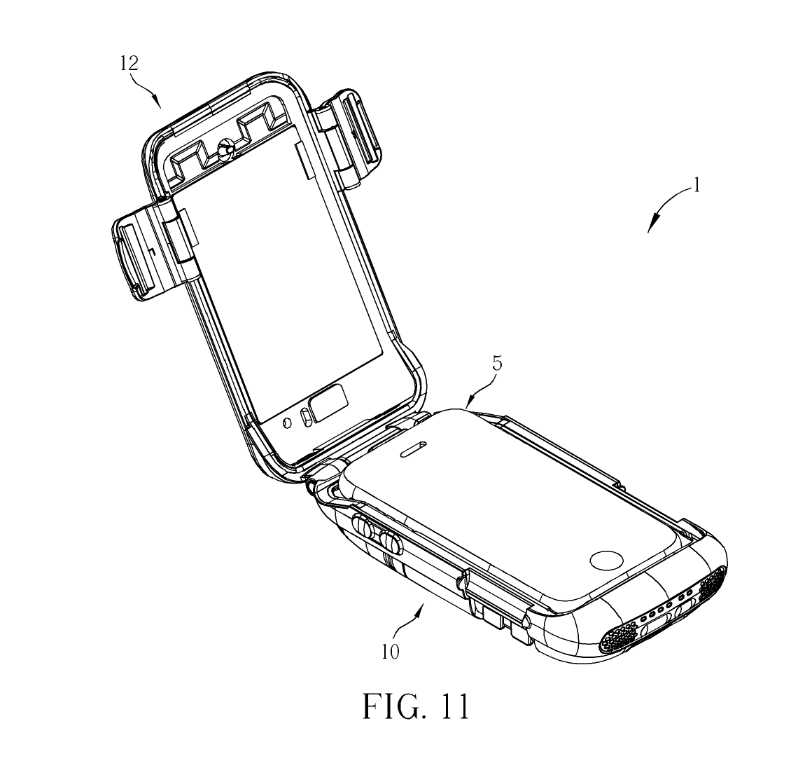

Referring to FIGS. 10 and 11, FIG. 10 illustrates another electronic device 5 and the electronic device 3 housed on the back cover 14, wherein FIG. 10(A) is a perspective view, FIG. 10(B) is a front view, and FIG. 10(C) is a side view; and FIG. 11 is a perspective view illustrating the electronic device 5 accommodated in the first accommodating space S1 without the back cover 14. As shown in FIG. 10, the size of the electronic device 5 is substantially equal to the total size of the electronic device 3 with the back cover 14. Therefore, the electronic device 5 can be accommodated in the first accommodating space 51 of the protective casing 1 immediately without the back cover 14, as shown in FIG. 11. That is to say, the protective casing 1 of the invention can be adapted for different electronic devices 3 and 5 with and without the back cover 14. If the user has the two electronic devices 3 and 5 at the same time, he or she can use the very same protective casing 1 to accommodate the electronic device 5 or the electronic device 3 with the back cover 14.

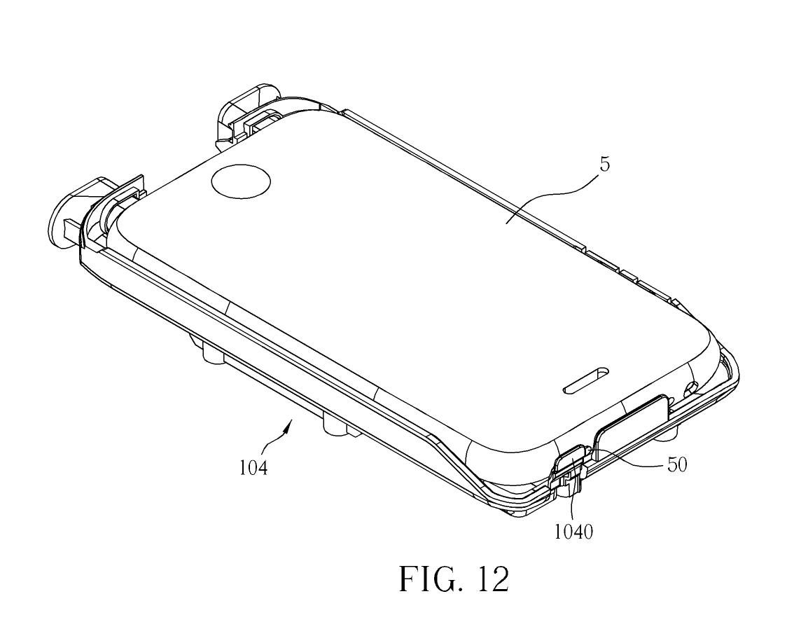

Referring to FIG. 12, FIG. 12 is a perspective view illustrating the electronic device 5 in FIG. 10 disposed on the partition member 104 in FIG. 9. As shown in FIG. 12, the electronic device 5 may have a power button 50, and the partition member 104 may have a resilient arm 1040 extending from the periphery of the partition member 104 and corresponding to the power button 50 of the electronic device 5. When the electronic device 5 is disposed on the partition member 104, the resilient arm 1040 abuts against the power button 50. Furthermore, the upper casing 12 may have a key structure 132 (as shown in FIG. 2) corresponding to the resilient arm 1040 of the partition member 104 (as shown in FIG. 12). In this manner, when the electronic device 5 is accommodated in the protective casing 1, the user can press the key structure 132 to drive the resilient arm 1040 to trigger the power button 50, so as to power on/off the electronic device 5.

Compared to the prior art, since the protective casing of the invention can be used to accommodate different electronic devices with or without the back cover, the protective casing of the invention equipped with the back cover will save cost for the user.

Those skilled in the art will readily observe that numerous modifications and alterations of the device and method may be made while retaining the teachings of the invention.

What is claimed is:

1. A protective casing adapted for an electronic device comprising:
a lower casing;
an upper casing cooperating with the lower casing to form a first accommodating space therebetween; and
a back cover detachably accommodated in the first accommodating space and used to house the electronic device.

2. The protective casing of claim 1, further comprising a hinge assembly for pivotally connecting the upper casing to the lower casing.

3. The protective casing of claim 1, wherein the upper casing comprises a transparent sheet which a touch panel of the electronic device abuts against when the electronic device is housed on the back cover and accommodated in the first accommodating space together with the back cover.

4. The protective casing of claim 1, wherein the back cover has an engaging structure extending from a periphery of the back cover, and the engaging structure is used to engage the electronic device.

5. The protective casing of claim 4, wherein the engaging structure is arc-shaped claws.

6. The protective casing of claim 1, wherein the back cover has a resilient arm extending from a periphery of the back cover and corresponding to a power button of the electronic device.

7. The protective casing of claim 6, wherein the upper casing has a key structure corresponding to the resilient arm of the back cover.

8. The protective casing of claim 1, wherein at least one recess is formed on a periphery of the back cover and is corresponding to at least one connector and/or button disposed on a periphery of the electronic device.

9. The protective casing of claim 8, wherein the at least one recess comprises a first recess formed on one side of the back cover and corresponding to a button disposed on one side of the electronic device.

10. The protective casing of claim 9, wherein the at least one recess further comprises a second recess formed on another side of the back cover and opposite to the first recess.

11. The protective casing of claim 1, wherein a skidproof structure is formed on an outer surface of the back cover.

12. The protective casing of claim 1, wherein the upper casing comprises two fastener members pivotally connected to opposite sides of the upper casing, the lower casing comprises two fastener structures formed on opposite sides of the lower casing, and the two fastener members are detachably fastened on the two fastener structures respectively.

13. The protective casing of claim 1, wherein at least one hole is formed on the upper casing, and the upper casing comprises at least one waterproof member covering the at least one hole respectively.

14. The protective casing of claim 1, wherein the upper casing comprises a ring-shaped waterproof member disposed on an inner side of the upper casing.

15. The protective casing of claim 1, wherein at least one hole is formed on the lower casing, and the lower casing comprises at least one waterproof member covering the at least one hole respectively.

16. The protective casing of claim 1, wherein the lower casing comprises a partition member disposed therein, the first accommodating space is above the partition member, and a second accommodating space is between the partition member and a bottom of the lower casing.

17. The protective casing of claim 16, further comprising a circuit board and a power supply unit disposed in the second accommodating space, the power supply unit is electrically connected to the circuit board, when the electronic device is housed on the back cover and accommodated in the first accommodating space together with the back cover, a connector of the electronic device is electrically connected to a connector of the circuit board, such that the power supply unit supplies power to the electronic device.

18. The protective casing of claim 17, further comprising a positioning unit disposed in the second accommodating space and electrically connected to the circuit board.
